(19) United States
(12) Patent Application Publication
(10) Pub. No.: US 2005/0071734 A1
(43) Pub. Date: Mar. 31, 2005

(54) Methods and systems for Viterbi decoding

(75) Inventors: Alexander J. Burr, Cambridge (GB); Timothy M. Dobson, Cambridge (GB); Sophie Wilson, Cambridge (GB)

Correspondence Address: STERNE, KESSLER, GOLDSTEIN & FOX PLLC, 1100 NEW YORK AVENUE, N.W., WASHINGTON, DC, 20005, US

(73) Assignee: Broadcom Corporation, Irvine, CA (US)

(21) Appl. No.: 10/948,544

(22) Filed: Sep. 24, 2004

Related U.S. Application Data
(60) Provisional application No. 60/505,861, filed on Sep. 26, 2003.

(51) Int. Cl. G06F 15/76; H03M 13/03; G06F 15/00

(52) U.S. Cl. 714/795

(57) ABSTRACT

An execution unit and a new set of instructions for performing Viterbi decoding are provided. The instructions can be built into an execution unit which executes other instructions, or in their own execution unit. In an example implementation, the new set of instructions are used in implementing a modem for a high bit rate single-pair high speed digital subscriber line (“SHDSL”) system. In the example implementation, the execution unit includes registers to hold the input metrics, so the same metrics do not need to be supplied for each instruction that uses them. The execution unit also includes registers to accumulate decision values, so that as many can be retrieved at once as makes best use of the data path out of the execution unit. The instructions may employ modulo arithmetic to avoid the necessity to rescale the state metrics.

### CROSS REFERENCE TO RELATED APPLICATIONS

This application claims the benefit of priority to U.S. Provisional Patent Application No. 60/505,861 filed Sep. 26, 2003, which is incorporated herein by reference in its entirety.

### BACKGROUND OF THE INVENTION

1. Field of the Invention

This invention relates to decoding convolutional codes and, more particularly, to Viterbi decoding.

2. Related Art

A convolutional code is a type of error correcting code that is routinely used for reliable communications of digital data over a noisy channel. Convolutional codes are, for example, commonly used within telecommunications applications, such as digital subscriber line (“DSL”), wireless 802.11, and ultra-wide band wireless applications.

Viterbi decoding is one method of decoding data streams that have been encoded with a convolutional encoder. Viterbi decoding performs optimal error correction for a given code to improve coding gain and produce reliable results at a digital receiver. To achieve a high level of performance, Viterbi decoding requires significant processing time because for each decode step it performs a calculation for each possible state of the encoder.

In older designs for decoders, a data stream flows though fixed-function hardware circuits that include the logic to perform Viterbi decoding. However, to provide greater flexibility with respect to decoder development, it has become more common to use software to perform the various functions in a decoder. Unfortunately, implementation of the Viterbi decoding algorithm in software is a complex calculation. As a result, when using conventional instructions (e.g., add, compare, select, etc) it may take many cycles to decode a single data symbol.

Given the growing consumer demand for high speed communications, such as DSL services, one processor within a DSL modem may need to handle several megabits per second. The Viterbi decode process for each symbol can therefore represent a significant proportion of the total computational cost of the modem. With increasing workloads (in terms of total data traffic passing through such a modem), it becomes necessary to improve the efficiency of the Viterbi decode process.

What is needed are methods and systems for efficiently implementing a Viterbi decoder.

### SUMMARY OF THE INVENTION

An execution unit and a new set of instructions for performing Viterbi decoding are provided. The instructions can be built into an execution unit which executes other instructions, or in their own execution unit. The execution unit can be built with hardware, software or a combination of hardware and software.

In an example implementation, the set of instructions are used in implementing a modem for a high bit rate single-pair high speed digital subscriber line (“SHDSL”) system. In the example implementation, the execution unit includes a number of registers including registers to hold input metrics, so the same metrics do not need to be supplied for each instruction that uses them. The execution unit also includes registers to accumulate decision values, so that as many can be retrieved at once as makes best use of the data path out of the execution unit. The instructions may employ modulo arithmetic to avoid the necessity to rescale the state metrics.

Additional features and advantages of the invention will be set forth in the description that follows. Yet further features and advantages will be apparent to a person skilled in the art based on the description set forth herein or may be learned by practice of the invention. The advantages of the invention will be realized and attained by the structure particularly pointed out in the written description and claims hereof as well as the appended drawings.

It is to be understood that both the foregoing summary and the following detailed description are exemplary and explanatory and are intended to provide further explanation of the invention as claimed.

### BRIEF DESCRIPTION OF THE DRAWINGS/FIGURES

The present invention will be described with reference to the accompanying drawing.

FIG. 1 is a diagram of a convolutional encoder.

FIG. 2 is a diagram of a convolutional encoder.

FIG. 3 is a trellis diagram.

FIG. 4A is a trellis diagram at time t₂ provided to demonstrate implementation of the Viterbi decoding algorithm.

FIG. 4B is a trellis diagram at time t₃ provided to demonstrate implementation of the Viterbi decoding algorithm.

FIG. 4C is a trellis diagram at time t₄ provided to demonstrate implementation of the Viterbi decoding algorithm.

FIG. 5 is a diagram of a processor having an execution unit for Viterbi decoding, according to an embodiment of the invention.

FIG. 6 is a flowchart of a method for generating state metrics and decision values used to implement the Viterbi decoding algorithm, according to an embodiment of the invention.

FIG. 7 is a diagram of a Viterbi decode computation, according to an embodiment of the invention.

FIG. 8 is a flowchart of a method for decoding a codeword received over an SHDSL communications channel, according to an embodiment of the invention.

### DETAILED DESCRIPTION OF THE INVENTION

While the present invention is described herein with reference to illustrative embodiments for particular applications, it should be understood that the invention is not limited thereto. Those skilled in the art with access to the teachings provided herein will recognize additional modifications, applications, and embodiments within the scope thereof and additional fields in which the invention would be of significant utility.

A convolutional code is a type of error correcting code that is routinely used for reliable communications of digital data over a noisy channel. A convolutional code accepts k binary symbols at its input and produces n binary symbols at its output, where the n output symbols are affected by v+k input symbols. Memory is incorporated into a convolutional code since v>0.

Convolutional codes are commonly specified by three parameters (n, k, m), where n equals the number of output bits, k equals the number of input bits and m equals the number of memory registers. The quantity k/n is referred to as the code rate, and is a measure of the efficiency of the code. Common values for k and n range from 1 to 8 with code rates typically ranging from ⅛ to ⅞. In exceptional cases, code rates can be as low as 1/100 or lower for deep space communication application.

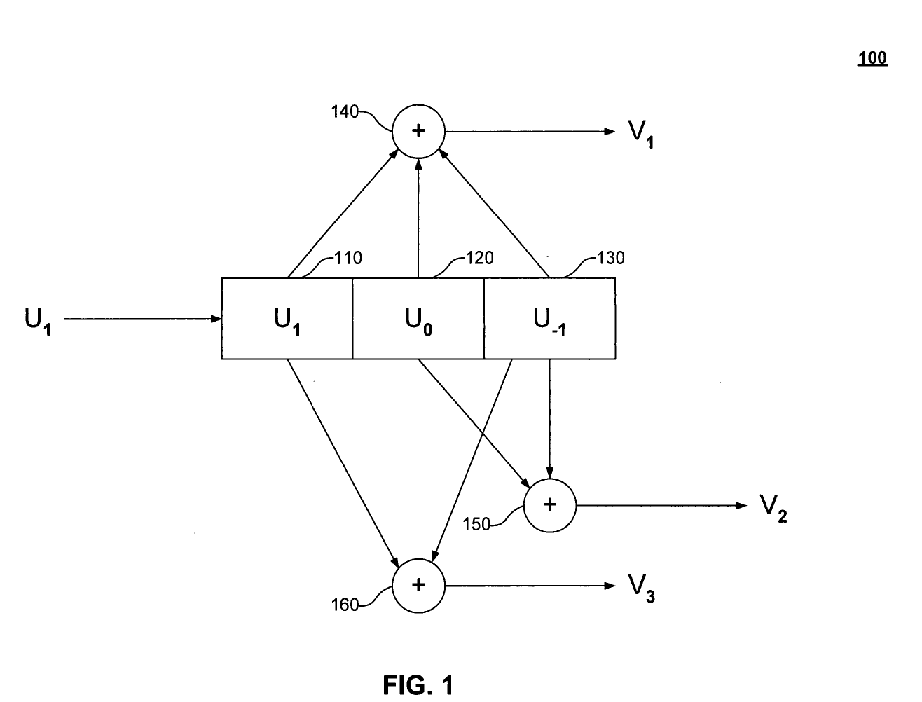

FIG. 1 shows a convolutional encoder 100. Convolutional encoder 100 has three memory registers 110, 120 and 130, an input bit, u₁, and three output bits v₁, v₂, and V₃. Convolutional encoder 100 includes three modulo-2 adders 140, 150, and 160 that produce output bits, v₁, v₂, and V₃, respectively, by adding up certain bits in the memory registers 110, 120 and 130. In particular, modulo-2 adder 140 is coupled to memory registers 110, 120, and 130. Modulo-2 adder 150 is coupled to memory registers 120 and 130. Modulo-2 adder 160 is coupled to memory registers 110 and 130. The selection of which memory registers are coupled to a particular modulo-2 adder is a function of a generator polynomial for each output bit. In this example, the generator polynomials are v₁=mod2(u₁+u₀+u₋₁), v₂=mod2(u₀+u₋₁) and v₃=mod2(u₁+u₋₁), where u₁ is the current input bit at time t, u₀ is the input bit from time t−1 and u₋₁ is the input bit from time t−2.

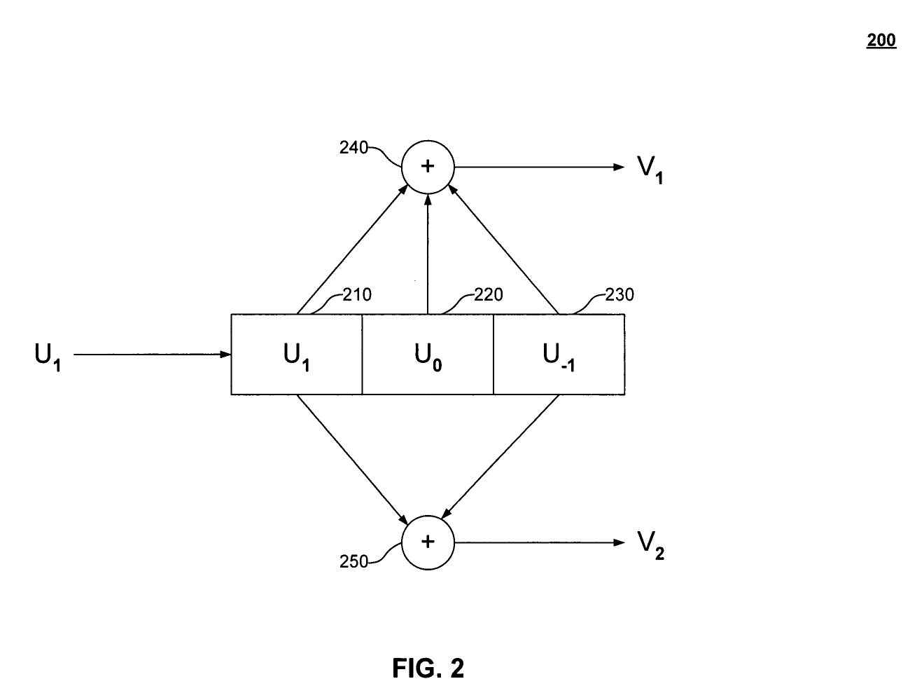

A trellis diagram can be used to describe how a convolutional encoder operates. FIG. 2 shows another simplified example of a convolutional encoder that will be used to demonstrate the use of a trellis diagram. Convolutional encoder 200 depicted in FIG. 2 has three memory registers 210, 220 and 230, input bit, u₁, and two output bits v₁ and v₂. Convolutional encoder 200 includes two modulo-2 adders 240 and 250 that produce output bits v₁ and v₂, respectively, by adding up certain bits in the memory registers 210, 220 and 230. Modulo-2 adder 240 is coupled to memory registers 210, 220 and 230. Modulo-2 adder 250 is coupled to memory registers 210 and 230. In this example, the generator polynomials are v₁=mod2(u₁+u₀+u₋₁), v₂=mod2(u₀+u₋₁), where u₁ is the current input bit at time t, u₀ is the input bit from time t−1 and u₋₁ is the input bit from time t−2.

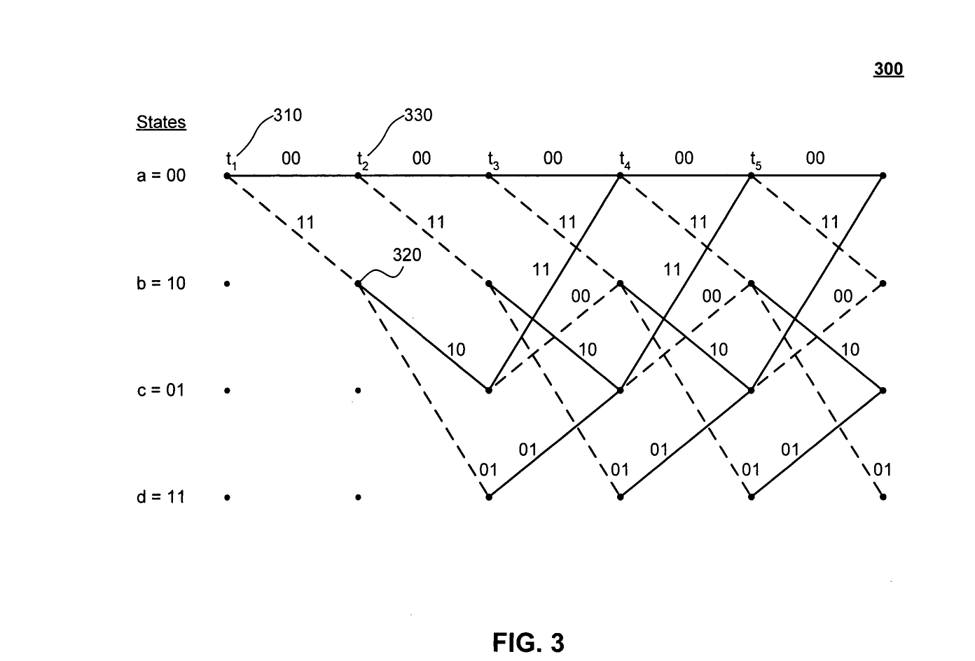

FIG. 3 shows trellis diagram 300 for convolutional encoder 200. A trellis diagram can be used to show the output and state of a convolutional encoder based on the input received and the immediate prior state of a convolutional encoder. For example, referring to FIG. 3, at time t₁, the state of convolutional encoder 200 is assumed to be a=00. In other words, memory registers 220 and 230 both contain the value of 0. On trellis diagram 300 when the input bit is 0, a solid line is used to connect a point in the trellis diagram to a next point at time t+1. Similarly, when an input bit is 1, a dashed line is used to connect a point in the trellis diagram to a next point at time t+1.

Referring to trellis diagram 300, when an input bit of 1 is received at time t1, convolutional encoder 200 outputs 11 and the state of convolutional encoder 200 moves to b=10. This is represented on trellis diagram 300 by the dashed line from point 310 to point 320. The “11” over the dashed line shows the output of convolutional encoder 200. At point 320, trellis diagram 300 shows that at time t₂, convolutional encoder 200 has a state of b=10. Alternatively, while at t₁ when an input bit of 0 is received, convolutional encoder 200 outputs a 00 and the state of convolutional encoder 200 stays at a=00. This transition is represented by the solid line from point 310 to point 330. The “00” over the solid line shows the output of convolutional encoder 200. At point 330, trellis diagram 300 also shows that at time t₂, convolutional encoder 200 has a state of b=00. Trellis diagram 300 shows all potential states for convolutional encoder 200 and possible transitions for six time cycles.

Once the outputs, or codewords, are generated they are transmitted to a receiver over a communication channel, which may be a wired or wireless communication channel. In either case, noise within the channel or other impairments may lead to errors within the transmitted signal. Thus, the received codeword may be different from the transmitted codeword. A decoder at the receive end of a communications link must then make an estimate to determine what was the actual transmitted codeword.

For example, at the receiving end of a transmission, a decoder must interpret the transmitted signal by decoding the encoding signal to obtain the information that is being transmitted for use. This information, for example, might represent data used to display a web page transmitted over a DSL connection between an end user and a central telephone switching office. In a DSL application only those bits transmitted over the most noisy parts of a channel are subject to convolutional coding.

A common decoding algorithm for convolutional codes is the Viterbi decoding algorithm. Viterbi decoding is described in, for example, Error Bounds for Convolutional Codes and an Asymptotically Optimum Decoding Algorithm, A J Viterbi, IEEE Trans. Inf. Theory, IT-13, pp 260-269, April 1967, incorporated herein by reference in its entirety. The Viterbi algorithm essentially performs maximum likelihood decoding. The algorithm involves calculating a measure of similarity, (which can also be referred to as a distance or state metric), between the received signal, at time t₁ and all the trellis paths entering each state at time tᵢ. The Viterbi algorithm removes from consideration those trellis paths that could not possibly be candidates for the maximum likelihood choice. When two paths enter the same state, the one having the best metric is chosen. This path is referred to as the surviving path.

Viterbi decoding performs optimal error correction for a given code, but it is particularly expensive because for each decode step it performs a calculation for each possible state of the encoder. A Viterbi decode step takes as input a (typically) small number of input metrics and a (typically) larger number of state metrics, and outputs new values for the state metrics, (representing a measure of similarity) and a decision or path value for each state. The metrics are typically four to sixteen bits in size, and the path values have the same number of bits that the convolutional code consumes on each step.

The Viterbi decoding algorithm can be illustrated by the following example. Assume that convolutional encoder 200 received an input data sequence, n, and transmitted a series of codewords, T. A Viterbi decoder received the transmitted code words as a received sequence R as illustrated below.

| Time: | t₁ | t₂ | t₃ | t₄ | t₅ |
|---|---|---|---|---|---|
| n: | 1 | 1 | 0 | 1 | 1 |
| T: | 11 | 01 | 01 | 00 | 01 |
| R: | 11 | 01 | 01 | 10 | 01 |

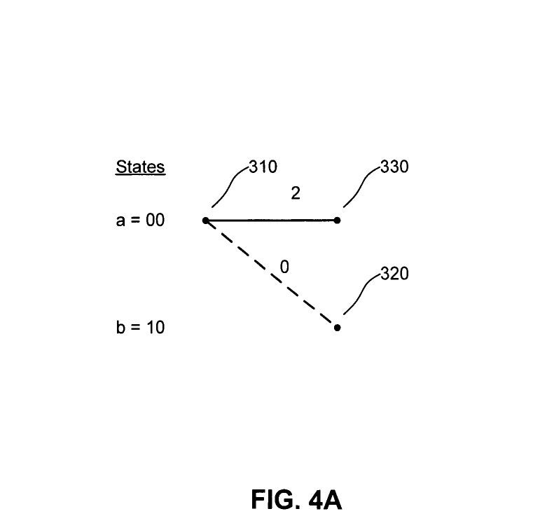

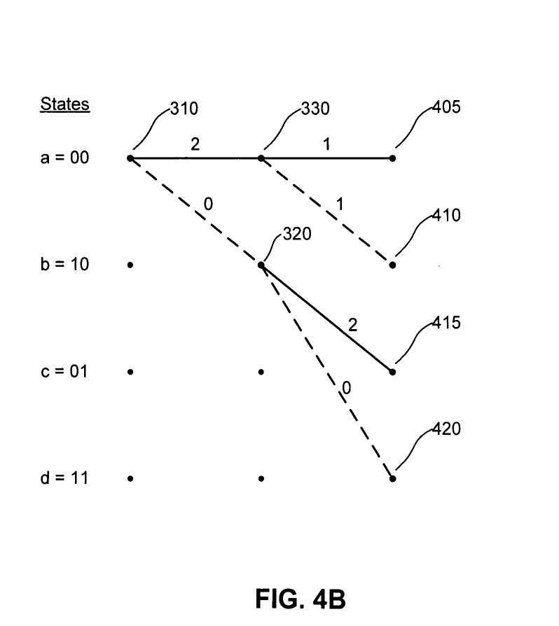

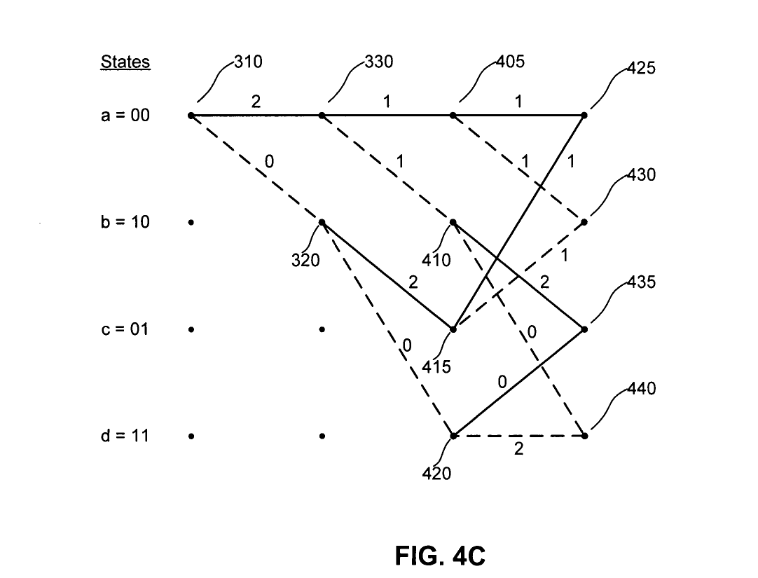

At the receiving end of the signal, the decoder does not know whether the signal is correct or whether it has been subject to some form of impairment thereby generating an error. At each time interval, a metric of similarity between the received codeword and the possible codewords is generated. The possible codewords are known based on knowledge of the type of convolutional code. In the above example, trellis diagram 300 shows the two possible paths to be from point 310 to point 330 (hereinafter, paths will be abbreviated in the form of “path 310-330”) or from point 310 to point 320. These are illustrated in FIG. 4A.

The similarity metric for path 310-330 is 0, while the similarity metric for path 310-320 is 2. The similarity metric is computed by comparing the received codeword to the possible output codeword shown in trellis diagram 300 for the path. For path 310-330, trellis diagram 300 shows the possible transmitted codeword to be 00. Recall that the received codeword is 11, thus the similarity metric is 2. The similarity metric is computed by determining the difference between the received codeword and the possible transmitted codeword. The higher the similarity metric the less likely the received codeword is actually the transmitted codeword. Within the Viterbi algorithm, when two paths in the trellis merge to a single state, the path with the highest similarity metric is removed. At time t₂ in the present example, no paths have merged to a single state, so additional data must be examined before any decisions on what the received signal actually is can be made.

FIG. 4B provides a portion of trellis diagram 300 showing the potential paths after time t₃. Referring to FIG. 4B, there are four possible paths. Path 310-330-405, path 310-330-410, path 310-320-415 and path 310-320-420. A similarity metric can be computed for each path, such that Path 310-330-405 has similarity metric equal to 3. Path 310-330-410 has a similarity metric equal to 3. Path 310-320-415 has a similarity metric equal to 2. Path 310-320-420 has a similarity metric equal to 0. Once again because no paths have converged to a single state, no decisions can be made with respect to what codeword an encoder would estimate to be the transmitted codeword.

FIG. 4C provides a portion of trellis diagram 300 showing the potential paths after time t₄. Referring to FIG. 4C, there are eight possible paths. These paths and their similarity metrics are shown below.

| Path | Similarity Metric |
|---|---|
| Path 310-330-405-425 | 4 |
| Path 310-330-410-435 | 5 |
| Path 310-330-410-440 | 3 |
| Path 310-330-405-430 | 4 |
| Path 310-320-415-425 | 3 |
| Path 310-320-415-430 | 3 |
| Path 310-320-420-435 | 0 |
| Path 310-320-420-440 | 2 |

In this case several of the paths converge to the same state. For example Path 310-330-405-425 and Path 310-320-415-425 both converge at point 425. In this case, the similarity metrics are compared for these two paths and the path with the highest similarity metric is removed from consideration. Thus, because Path 310-330-405-425 has a similarity metric that is higher than that of Path 310-320-415-425, Path 310-330-405-425 is eliminated from consideration. This process can be done for each of the pairs of paths that converge on a single state. Upon completion of the process in this example, all remaining paths have the stem of Path 310-320. As a result, the Viterbi decoding algorithm would conclude that the transmitted codeword for time t₁ was 11.

The example provided through FIGS. 3 and 4 demonstrates how quickly the Viterbi decoding algorithm can become complex even for a simple convolutional encoder with a limited number of states. The challenges of decoding a received signal that has been encoded using convolutional coding varies by the application, the speed of transmission and the type of convolutional coding. In general, however, improvements are needed to more efficiently decode signals using an implementation of the Viterbi decoding algorithms. The present invention provides an execution unit, method and instructions that address this need.

The above examples of Viterbi coding involved what is referred to as “hard decision” Viterbi decoding. Another related approach to Viterbi decoding is “soft decision” decoding, which takes into account the analog nature of an input. The implementation examples described below use “soft decision” decoding. However, the scope of invention is not limited to “soft decision” decoding, and can be applied to hard decision decoding, as will be known by individuals skilled in the relevant arts based on the teachings herein.

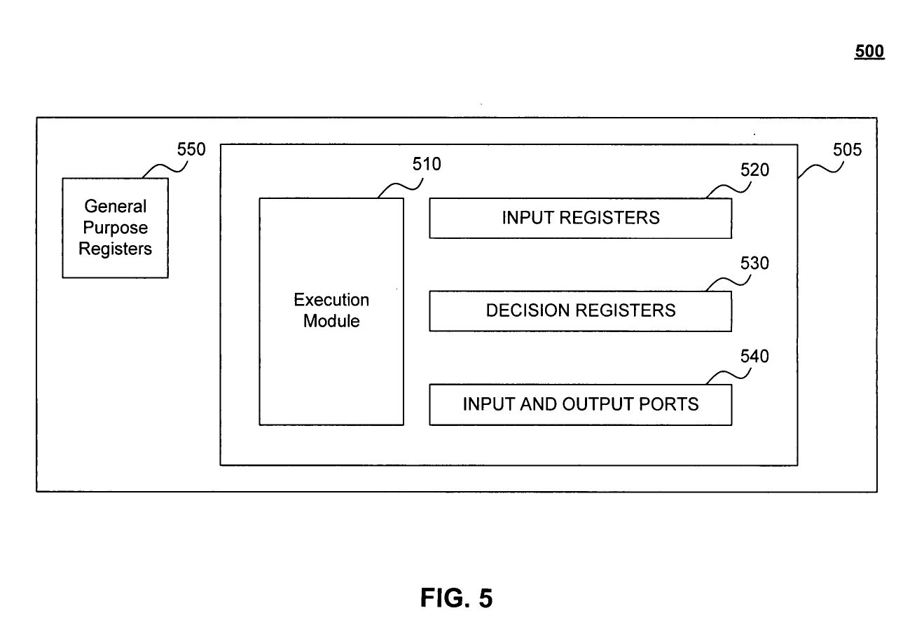

FIG. 5 is a diagram of a portion of processor 500, according to an embodiment of the present invention. Processor 500 includes execution module 505 and general purpose registers 550. Execution unit 505 includes execution module 510, input registers 520, decision registers 530 and input and output ports 540. Execution module 510 contains the instructions necessary to perform a Viterbi decode using the approach presented herein. Execution module 510 performs these instructions, accesses information needed for the instructions that are located in the registers and stores results in the registers so they may be used by other instructions and processes within a decoder. Processor 500 can be located within a decoder used to decode convolutional codes used to encode communication signals. The execution unit can be built with hardware, software or a combination of hardware and software. Execution unit 505 can be included in processor 500 as illustrated in FIG. 5, or in other types of general purpose hardware as will be known to individuals skilled in the relevant arts.

General purpose registers 550 are 64 bit general purpose registers. General purpose registers 550 are used to hold state metrics and selection values. When used to hold state metrics, general purpose registers 550 can be referred to as state registers. Similarly, when used to hold selection values, general purpose registers 550 can be referred to as selection registers. Data between execution unit 505 and general purpose registers 550 is exchanged through input and output ports 540.

Input registers 520 and decision registers 530 are special purpose registers that are 8 bit registers. Special purpose registers have an advantage over general purpose registers in that they may be able to be accessed faster and can overcome certain restrictions which the design of a processor may have placed on the use of general purpose registers. For example, an execution unit may be able to only read a fixed number of general purpose registers.

In an embodiment, there are 24 special purpose registers. These special purpose registers can be denoted as MX0, MX1, MX2, MX3 (hereinafter this set of four registers shall be referred to as MX0 . . . 3), MY0, MY1, MY2, MY3, (hereinafter this set of four registers shall be referred to as MY0 . . . 3), DX0, DX1, DX2, DX3, DX4, DX5, DX6, DX7, (hereinafter this set of eight registers shall be referred to as DX0 . . . 7), DY0, DY1, DY2, DY3, DY4, DY5, DY6, DY7 (hereinafter this set of eight registers shall be referred to as DY0 . . . 7).

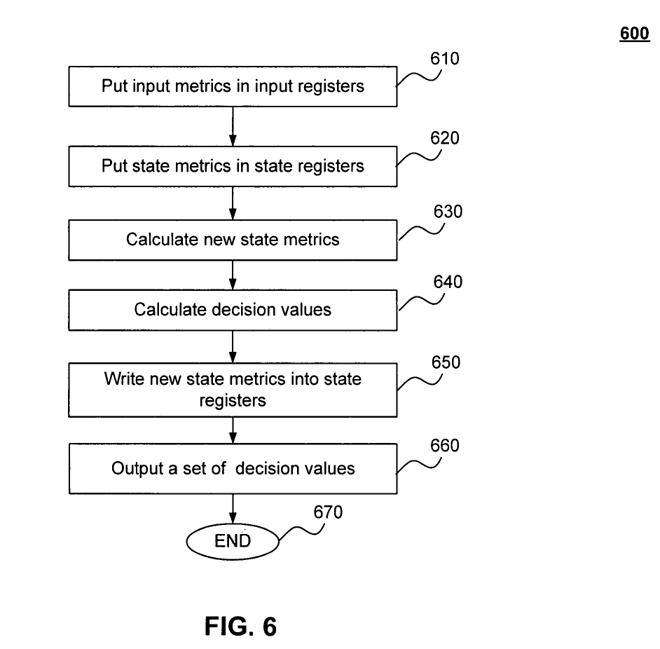

FIG. 6 is a flowchart of a method 600 for generating state metrics and decision values used to implement a Viterbi decoding algorithm, according to an embodiment of the present invention. Method 600 begins in step 610. In step 610 input metrics are placed into input metric registers, such as input registers 520. In step 620 state metrics are placed into state metric registers, such as general purpose registers 550. In step 630 new state metrics are calculated. In step 640 new decision values are calculated. Likewise these new state metrics and decision values can be calculated using a VAC command as is described below.

In step 650 the new state metrics are written to general purpose registers 550. In step 660 the decision values generated in step 640 are put into special purpose registers, such as decision registers 530. In step 670, method 600 ends.

An embodiment of method 600 can be implemented using a VAC instruction. A summary of the VAC instruction is provided, followed by a detailed implementation. When a VAC instruction is executed, some state values are transferred from general purpose registers 550 to execution unit 505. Some selection values are transferred from the general purpose registers 550 to execution unit 505. Selection values are derived from the kind of convolutional code used, and are thus unchanged during the decoding of a data stream encoded using a particular convolutional code. The VAC calculation uses the above values, plus input metric values held in input registers 520. Decision values are written to decision registers 530. Updated state values are transferred out of execution unit 505 to general purpose registers 550.

The particular split between the general purpose registers and the special purpose registers was chosen to make efficient use of the limited number of general purpose registers 550, which an instruction can read and write in processor 500. Alternatively, the number of input and output ports 540 can be increased, however, this also increases the cost and complexity of a processor, such as processor 500.

In an embodiment of method 600, the following instruction set and instructions can be used. The instructions used are as follows:

| Instruction | Description |
|---|---|
| VPUTMX metrics | Put metrics into special purpose metric registers |
| | MX0 . . . MX3 |
| VPUTMY metrics | Put metrics into special purpose metric registers |
| | MY0 . . . MY3 |
| VAC0 out0, out1, | Using input metrics previously written by |
| out2, out3, in0, in1, | VPUTMX and VPUTMX and state metrics |
| in2, in3, de0, de1 | from in0 . . . in3, calculate new state metrics |
| | and decision values. State metrics are written out |
| | to out0 . . . out3 and decision values are written to |
| | decision registers DX0, DX1, DY0 and DY1. |
| | de0 and de1 are used to select which input |
| | metrics to use in the calculation. |
| VAC1 | This command is the same as VAC0, except |
| | that decision values are written to decision |
| | registers DX2, DX3, DY2 and DY3. |
| VAC2 | This command is the same as VAC0, except |
| | that decision values are written to decision |
| | registers DX4, DX5, DY4 and DY5. |
| VAC3 | This command is the same as VAC0, except |
| | that decision values are written to decision |
| | registers DX6, DX7, DY6 and DY7. |
| VGETDX decisions | Read decisions from decision registers |
| | DX0 . . . DX7. |
| VGETDY decisions | Read decisions from decision registers |
| | DY0 . . . DY7. |
| VGETMX metrics | Get metrics from special purpose metric |
| | registers MX0 . . . MX3. |
| VGETMY metrics | Get metrics from special purpose metric |
| | registers MY0 . . . MY3. |
| VPUTDX decisions | Put decisions into special purpose decision |
| | registers DX0 . . . DX7. |
| VPUTDY decisions | Put decisions into special purpose decision |
| | registers DY0 . . . DY7. |

The VAC instructions may employ modulo arithmetic to avoid the necessity to rescale the state metrics, as described in, “An alternative to metric rescaling in Viterbi Decoders”, Andries P Hekstra, IEEE Trans Comm Vol 37 no 11,pp1220-1222, November 1989, incorporated herein by reference in its entirety. Hekstra demonstrated that the input/output behavior of the Viterbi algorithm is unaffected by the application of a modulo operator to all metric variables, when the range of the modulo operator is sufficiently large and approximately symmetric around zero. Hekstra further observed that this modulo operator corresponds to the overflow mechanism in two's complement arithmetic and therefore has no hardware cost.

VGETMX/Y and VPUTDX/Y are not strictly necessary for the operation of the Viterbi algorithm, since the metric registers are never altered by the VAC execution unit, nor the decision registers read by the VAC execution unit. These commands are used in a multi-threaded environment, where one Viterbi operation may get interrupted by a higher priority thread, which may want to do Viterbi operations itself. In this case the context-switch code can use VGETMX/Y and VGETDX/Y to read the metric and decision registers and save them in memory, and then when the thread is resumed these registers can be restored using VPUTMX/Y and VPUTDX/Y, so that the original Viterbi operation can continue as if nothing happened. In a single-threaded environment VGETMX/Y and VPUTDX/Y are not likely to be needed.

The present invention combines this principle with the use of complex register structures that minimizes execution cycles to provide an execution unit that can efficiently perform the Viterbi decoding algorithm at high data rates.

The instruction VAC<n> can be split into four independent sub operations, such that

$$VAC < n > out0 , out1 , out2 , out3 , in0 , in1 , in3 , de0 , de1 = \\ VACBX < 2 n + 0 > out0 , in0 , in1 , de0$$

$$VACTX < 2 n + 1 > out2 , in0 , in1 , de0$$

$$VACBX < 2 n + 0 > out1 , in2 , in3 , de1$$

$$VACTX < 2 n + 1 > out3 , in2 , in3 , de1$$

When treating the VAC instruction as four independent sub operations, out<n> and in<n> are treated as arrays of 8 bytes. de0 and de1 are each treated as arrays of 32 two-bit values and MX0 . . . 3 is treated as an array of 4 bytes. In each instruction,
all additions are performed modulo 256,
MIN(a,b) is defined as if((a−b)&0×80) then a otherwise b, which provides the modulo arithmetic minimum, and
WHICHMIN (a,b) is defined as if((a−b&0×80) then 0 otherwise 1.

VACBX<n> is defined as follows:

out[0] = MIN( in0[0] + MX[ de[0] ],in1[0]+MX[de[16]])
out[1] = MIN( in0[0] + MX[ de[1] ],in1[0]+MX[de[17]])
out[2] = MIN( in0[1] + MX[ de[2] ],in1[1]+MX[de[18]])
out[3] = MIN( in0[1] + MX[ de[3] ],in1[1]+MX[de[19]])
out[4] = MIN( in0[2] + MX[ de[4] ],in1[2]+MX[de[20]])
out[5] = MIN( in0[2] + MX[ de[5] ],in1[2]+MX[de[21]])
out[6] = MIN( in0[3] + MX[ de[6] ],in1[3]+MX[de[22]])
out[7] = MIN( in0[3] + MX[ de[7] ],in1[3]+MX[de[23]])
DX<n>[0] = WHICHMIN( in0[0] + MX[ de[0] ],in1[0]+MX[de[16]])
DX<n>[1] = WHICHMIN( in0[0] + MX[ de[1] ],in1[0]+MX[de[17]])
DX<n>[2] = WHICHMIN( in0[1] + MX[ de[2] ],in1[1]+MX[de[18]])
DX<n>[3] = WHICHMIN( in0[1] + MX[ de[3] ],in1[1]+MX[de[19]])
DX<n>[4] = WHICHMIN( in0[2] + MX[ de[4] ],in1[2]+MX[de[20]])
DX<n>[5] = WHICHMIN( in0[2] + MX[ de[5] ],in1[2]+MX[de[21]])
DX<n>[6] = WHICHMIN( in0[3] + MX[ de[6] ],in1[3]+MX[de[22]])
DX<n>[7] = WHICHMIN( in0[3] + MX[ de[7] ],in1[3]+MX[de[23]])
where, DX<n>[i] is bit i of DX<n>

VACBY<n> is defined as VACBX<n> but uses MY and DY, and can be represented as follows:

out[0] = MIN( in0[0] + MY[ de[0] ],in1[0]+MY[de[16]])
out[1] = MIN( in0[0] + MY[ de[1] ],in1[0]+MY[de[17]])
out[2] = MIN( in0[1] + MY[ de[2] ],in1[1]+MY[de[18]])
out[3] = MIN( in0[1] + MY[ de[3] ],in1[1]+MY[de[19]])
out[4] = MIN( in0[2] + MY[ de[4] ],in1[2]+MY[de[20]])
out[5] = MIN( in0[2] + MY[ de[5] ],in1[2]+MY[de[21]])
out[6] = MIN( in0[3] + MY[ de[6] ],in1[3]+MY[de[22]])
out[7] = MIN( in0[3] + MY[ de[7] ],in1[3]+MY[de[23]])
DY<n>[0] = WHICHMIN( in0[0] + MY[ de[0] ],in1[0]+MY[de[16]])
DY<n>[1] = WHICHMIN( in0[0] + MY[ de[1] ],in1[0]+MY[de[17]])
DY<n>[2] = WHICHMIN( in0[1] + MY[ de[2] ],in1[1]+MY[de[18]])
DY<n>[3] = WHICHMIN( in0[1] + MY[ de[3] ],in1[1]+MY[de[19]])
DY<n>[4] = WHICHMIN( in0[2] + MY[ de[4] ],in1[2]+MY[de[20]])
DY<n>[5] = WHICHMIN( in0[2] + MY[ de[5] ],in1[2]+MY[de[21]])
DY<n>[6] = WHICHMIN( in0[3] + MY[ de[6] ],in1[3]+MY[de[22]])
DY<n>[7] = WHICHMIN( in0[3] + MY[ de[7] ],in1[3]+MY[de[23]])
where, DY<n>[i] is bit i of DY<n>

VACTX<n> is defined as VACBX<n> except that it uses different bytes from within the various registers, as defined below:

out[0] = MIN( in0[4] + MX[ de[08] ],in1[4]+MX[de[24]])
out[1] = MIN( in0[4] + MX[ de[09] ],in1[4]+MX[de[25]])
out[2] = MIN( in0[5] + MX[ de[10] ],in1[5]+MX[de[26]])
out[3] = MIN( in0[5] + MX[ de[11] ],in1[5]+MX[de[27]])
out[4] = MIN( in0[6] + MX[ de[12] ],in1[6]+MX[de[28]])
out[5] = MIN( in0[6] + MX[ de[13] ],in1[6]+MX[de[29]])
out[6] = MIN( in0[7] + MX[ de[14] ],in1[7]+MX[de[30]])
out[7] = MIN( in0[7] + MX[ de[15] ],in1[7]+MX[de[31]])
DX<n>[0] =WHICHMIN( in0[4] + MX[ de[08] ],in1[4]+MX[de[24]])
DX<n>[1]= WHICHMIN( in0[4] + MX[ de[09] ],in1[4]+MX[de[25]])
DX<n>[2]= WHICHMIN( in0[5] + MX[ de[10] ],in1[5]+MX[de[26]])
DX<n>[3]= WHICHMIN( in0[5] + MX[ de[11] ],in1[5]+MX[de[27]])
DX<n>[4]= WHICHMIN( in0[6] + MX[ de[12] ],in1[6]+MX[de[28]])
DX<n>[5]=WHICHMIN( in0[6] + MX[ de[13] ],in1[6]+MX[de[29]])
DX<n>[6]= WHICHMIN( in0[7] + MX[ de[14] ],in1[7]+MX[de[30]])
DX<n>[7]= WHICHMIN( in0[7] + MX[ de[15] ],in1[7]+MX[de[31]])
where, DX<n>[i] is bit i of DX<n>

VACTY<n> is defined as VACTX<n> but uses MY and DY, and can be represented as follows:

out[0] = MIN( in0[4] + MY[ de[08] ],in1[4]+MY[de[24]])
out[1] = MIN( in0[4] + MY[ de[09] ],in1[4]+MY[de[25]])
out[2] = MIN( in0[5] + MY[ de[10] ],in1[5]+MY[de[26]])
out[3] = MIN( in0[5] + MY[ de[11] ],in1[5]+MY[de[27]])
out[4] = MIN( in0[6] + MY[ de[12] ],in1[6]+MY[de[28]])
out[5] = MIN( in0[6] + MY[ de[13] ],in1[6]+MY[de[29]])
out[6] = MIN( in0[7] + MY[ de[14] ],in1[7]+MY[de[30]])
out[7] = MIN( in0[7] + MY[ de[15] ],in1[7]+MY[de[31]])
DY<n>[0] =WHICHMIN( in0[4] + MY[ de[08] ],in1[4]+MY[de[24]])
DY<n>[1]= WHICHMIN( in0[4] + MY[ de[09] ],in1[4]+MY[de[25]])
DY<n>[2]= WHICHMIN( in0[5] + MY[ de[10] ],in1[5]+MY[de[26]])
DY<n>[3]= WHICHMIN( in0[5] + MY[ de[11] ],in1[5]+MY[de[27]])
DY<n>[4]= WHICHMIN( in0[6] + MY[ de[12] ],in1[6]+MY[de[28]])
DY<n>[5]=WHICHMIN( in0[6] + MY[ de[13] ],in1[6]+MY[de[29]])
DY<n>[6]= WHICHMIN( in0[7] + MY[ de[14] ],in1[7]+MY[de[30]])
DY<n>[7]= WHICHMIN( in0[7] + MY[ de[15] ],in1[7]+MY[de[31]])
where, DY<n>[i] is bit i of DY<n>.

The VAC instruction can be partitioned across multiple execution units. In this case, registers are also partitioned across the multiple execution units.

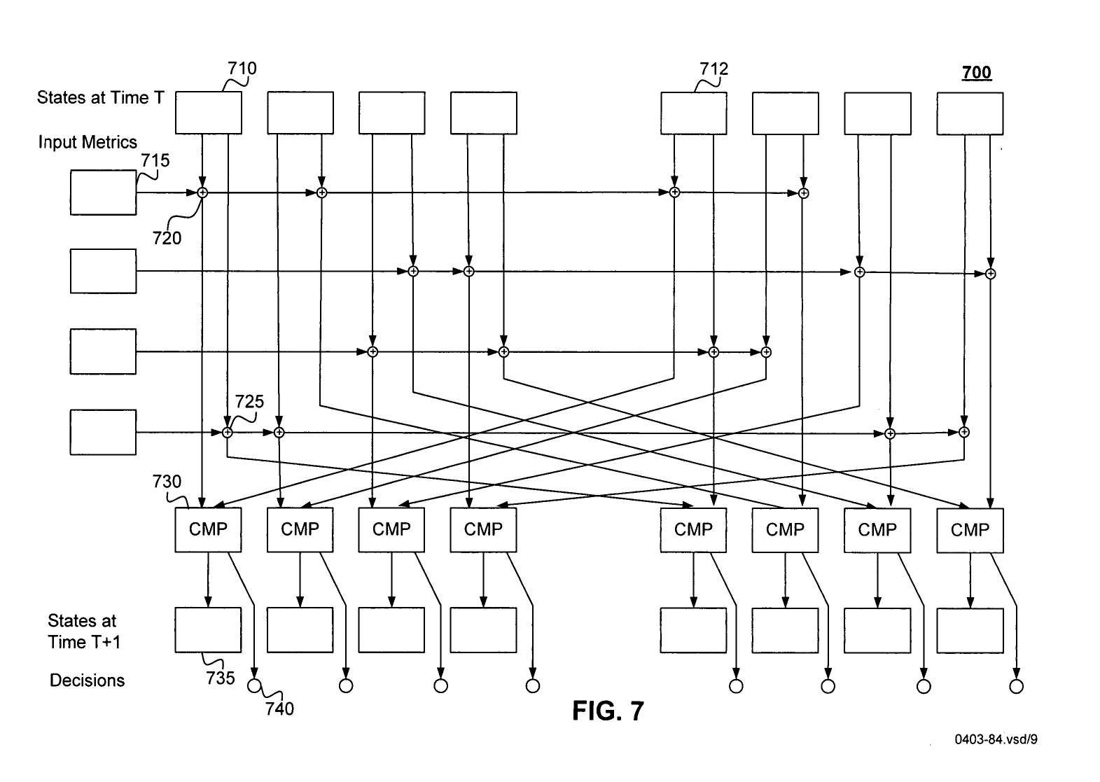

FIG. 7 is a diagram showing the implementation of one VAC command to produce the Viterbi decode computation. In particular, state metrics 710 represent a state of an encoder at time T. A value is generated by adding state metrics 710 to input metrics 715, possibly by using modulo arithmetic at adder 720. This value is provided to compare module 730. Additionally, a second value is provided to compare module 730 based on state metrics 712 and input metrics 715. Comparator 730 produces an output that represents a new value for state metrics 710, which is indicated in the diagram by state metrics 735. This represents state metrics 710 at time T+1. Additionally, compare block 730 provides decision 740 that can be used by the execution unit to determine the most likely path within a trellis diagram and ultimately to estimate the value of a transmitted codeword. FIG. 7 represents one quarter of the decoding operation used to implement a full VAC instruction.

The present invention can be used to decode signals received by an SHDSL modem. SHDSL refers to single-pair high speed digital subscriber line (SHDSL) service as defined in ITU-T Standard G.991.2 adopted December 2003 (hereinafter ITU-T G.991.2 Standard). The present invention is not, however, limited to SHDSL. Based on the teachings herein, individuals skilled in the relevant arts will be able to apply the present invention to other communication applications, such as other forms of DSL, 802.11 wireless applications and ultra-wide band wireless applications, for example. SHDSL is an international standard for symmetric DSL.

SHDSL provides high speed broadband communications typically from a telephone central office switch location to a user premises (e.g., a home or business). SHDSL provides for sending and receiving high-speed symmetrical data streams over a single pair of copper wires at rates between 192 kbps and 2.31 Mbps.

SHDSL uses a feed forward code, which is a particular kind of convolutional code in which the state at time T is a function of a finite number of previous inputs. A feed forward convolutional encoder used for SHDSL produces two output bits for each input bit per step. The number of bits required to store its state is implementation specific, however, the ITU-T G.991.2 standard specifies that up to 21 bits can be used. By comparison and to demonstrate the potential complexity of decoding an SHDSL signal only 2 bits would be required to store the state of convolutional encoder 200.

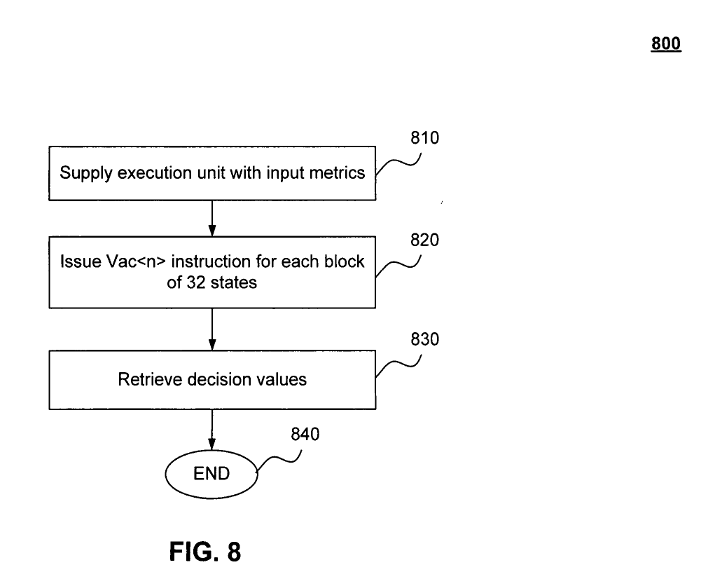

FIG. 8 is a flowchart of a method 800 for decoding a codeword received over an SHDSL communications channel. Method 800 begins in step 810. In step 810 an execution unit, such as execution unit 505, is supplied with input metrics. These input metrics can be supplied by instructions VPUTMX metrics and VPUTMY metrics, for example.

In step 820, a VAC <n> instruction is issued for each block of 32 states. In step 830, decision values generated by the VAC instruction are retrieved. Steps 820 and 830 would need to be repeated each time the registers holding these values fill up. These decision values are then interpreted to determine the most likely path or paths within a trellis diagram to enable an execution unit to determine the most likely codeword that was transmitted. Once the most likely codeword is determined, a decoder would provide the information to the next stage in a receiver for interpreting the information received.

### Conclusions

The present invention has been described above with the aid of functional building blocks illustrating the performance of specified functions and relationships thereof. The boundaries of these functional building blocks have been arbitrarily defined herein for the convenience of the description. Alternate boundaries can be defined so long as the specified functions and relationships thereof are appropriately performed. Any such alternate boundaries are thus within the scope and spirit of the claimed invention. One skilled in the art will recognize that these functional building blocks can be implemented by discrete components, application specific integrated circuits, processors executing appropriate software and the like and combinations thereof.

While various embodiments of the present invention have been described above, it should be understood that they have been presented by way of example only, and not limitation. Thus, the breadth and scope of the present invention should not be limited by any of the above-described exemplary embodiments, but should be defined only in accordance with the following claims and their equivalents.

1. An execution unit for performing a Viterbi decoding algorithm, comprising within a processor having general purpose registers:
an execution module including a set of Viterbi decoding instructions that determines updated state metrics and decision values for the Viterbi decoding algorithm;
a plurality of input registers for holding input metrics; and
a plurality of decision registers for holding decision values.

2. The execution unit of claim 1, wherein said input and decision registers are eight bit registers.

3. The execution unit of claim 1, wherein said set of Viterbi decoding instructions use modulo arithmetic to avoid the necessity to rescale state metrics.

4. The execution unit of claim 1, wherein said set of Viterbi decoding instructions comprise:
at least one first command to put metrics into a set of input registers;
a second command to calculate new state metrics and decision values used to determine a transmitted codeword based on the metrics placed into the set of said input registers; and
at least one third command to read decisions for a set of decision registers that contain the decisions values.

5. The execution unit of claim 4, wherein said set of Viterbi decoding instructions further comprise:
at least one fourth command to get metrics from a set of said input registers; and
at least one fifth command to put decision values into a set of said decision registers.

6. The execution unit of claim 1, wherein said set of Viterbi decoding instructions comprises:
a VAC0 out0, out1, out2, out3, in0, in1, in2, in3, de0, de1 instruction;
a VAC1 out0, out1, out2, out3, in0, in1, in2, in3, de0, de1 instruction;
a VAC2 out0, out1, out2, out3, in0, in1, in2, in3, de0, de1 instruction;
a VAC3 out0, out1, out2, out3, in0, in1, in2, in3, de0, de1 instruction;
a VPUTMX metrics instruction;
a VPUTMY metrics instruction;
a VGETDX decisions instruction; and
a VGETDY decisions instruction.

7. The execution unit of claim 6, wherein said set of Viterbi decoding instructions further comprises:
a VGETMX metrics instruction;
a VGETMY metrics instruction;
a VPUTDX decisions instruction; and
a VPUTDY decisions instruction.

8. An execution unit for performing a Viterbi decoding algorithm, comprising:
an execution module including a VAC instruction; and
a plurality of registers for holding input metrics, state metrics and decision values.

9. A method for performing a Viterbi decoding algorithm, comprising:
(a) putting input metrics into one or more input registers;
(b) putting state metrics into one or more state registers;
(c) calculating new state metrics;
(d) calculating decisions values;
(e) writing new state metrics into one or more state registers; and
(f) writing decision values into one or more decision registers.

10. The method of claim 9, wherein step (a) further comprises placing the input metrics in one or more registers, whereby the same input metrics do not need to be supplied for each instruction that uses them.

11. The method of claim 9, wherein step (f) further comprises optimizing the number of registers used to hold decision values, whereby maximizing the number of decision values that can be retrieved based on a data path out of the execution unit.

12. The method of claim 9, wherein steps (c), (d), (e) and (f) further comprise issuing a VAC instruction.

13. The method of claim 12, wherein issuing a VAC instruction further comprises splitting a VAC instruction into four independent sub operations.

14. The method of claim 12, wherein issuing a VAC instruction further comprises partitioning the VAC instruction across two or more independent execution units.

15. A method for decoding a codeword received over an SHDSL communications channel, comprising:
(a) supplying an execution unit with input metrics;
(b) issuing a VAC<n> instruction for each block of thirty-two states; and
(c) retrieving decision values from decision registers.
